(19) United States
(12) Patent Application Publication
(10) Pub. No.: US 2026/0269585 A1
(43) Pub. Date: Sep. 10, 2026

(54) ELECTRICAL JUNCTION BOX

(71) Applicants: AutoNetworks Technologies, Ltd., Yokkaichi-shi (JP); Sumitomo Wiring Systems, Ltd., Yokkaichi-shi (JP); Sumitomo Electric Industries, Ltd., Osaka-shi (JP)

(72) Inventors: Kiyofumi KAWAGUCHI, Yokkaichi-shi (JP); Haruki OKANO, Yokkaichi-shi (JP)

(73) Assignees: AutoNetworks Technologies, Ltd., Yokkaichi-shi (JP); Sumitomo Wiring Systems, Ltd., Yokkaichi-shi (JP); Sumitomo Electric Industries, Ltd., Osaka-shi (JP)

(21) Appl. No.: 19/550,540

(22) Filed: Feb. 26, 2026

(30) Foreign Application Priority Data
Mar. 10, 2025 (JP) 2025-037124

(51) Int. Cl. H02G 3/14

(52) U.S. Cl. CPC H02G 3/14

(57) ABSTRACT

An electrical junction box includes a first case and a second case. The first case includes a first body, an open surface that faces the first body and is open upward (in the first direction), a side surface portion that faces in a lateral direction intersecting the vertical direction (first direction), and a locking protrusion that protrudes in the lateral direction from the side surface portion. The second case includes a second body that closes the open surface, and an elastic locking portion. The elastic locking portion includes a base end portion that protrudes in the lateral direction from the second body, a locking body that is disposed away from the side surface portion in the lateral direction and are locked to the locking protrusion to keep the first and seconds case in a closed state, and a bent portion that connects the base end portion and the locking body.

### CROSS-REFERENCE TO RELATED APPLICATIONS

This application claims priority of Japanese Patent Application No. JP 2025-037124 filed on Mar. 10, 2025, the content of which is incorporated herein.

### TECHNICAL FIELD

The present disclosure relates to an electrical junction box.

### BACKGROUND

JP 2020-108306A discloses an electrical junction box configured such that a latching piece provided on a cover is locked to a latching hook provided on a case and thereby the cover and the case are coupled to each other.

JP 2020-108306A is an example of related art.

### SUMMARY

The latching piece described in JP 2020-108306A is elastically deformable in the thickness direction due to a slit being formed in a side plate of the cover. Here, when the rising length of the side plate needs to be reduced for the purpose of height reduction and the like, the length of the slit cannot be sufficiently secured, which leads to a concern that the latching piece cannot be elastically deformed sufficiently.

The electrical junction box of the present disclosure was made based on the foregoing circumstances, and it is an object of the present disclosure to provide an electrical junction box capable of smoothly locking cases to each other while reducing the height.

An electrical junction box of the present disclosure includes:

a first case; and

a second case,

wherein the first case includes:

a first body;

an open surface that faces the first body and is open in a first direction;

a side surface portion that faces in a lateral direction intersecting the first direction; and

a locking protrusion that protrudes in the lateral direction from the side surface portion,

the second case includes:

a second body that closes the open surface; and

an elastic locking portion, and

the elastic locking portion includes:

a base end portion that protrudes from the second body in the lateral direction;

a locking body that is disposed away from the side surface portion in the lateral direction and is locked to the locking protrusion to keep the first case and the second case in a closed state; and

a bent portion that connects the base end portion and the locking body.

With the present disclosure, it is possible to smoothly lock cases to each other while reducing the height.

### BRIEF DESCRIPTION OF THE DRAWINGS

FIG. 1 is an exploded perspective view of an electrical junction box according to Embodiment 1;

FIG. 2 is an enlarged perspective view of a relevant portion showing a locking protrusion and a portion therearound;

FIG. 3 is an enlarged side view of a relevant portion showing the locking protrusion and the portion therearound;

FIG. 4 is an enlarged perspective view of a relevant portion showing an elastic locking portion;

FIG. 5 is an enlarged plan view of a relevant portion showing the elastic locking portion;

FIG. 6 is an enlarged side cross-sectional view of a relevant portion showing a state in which the elastic locking portion is inserted into a latching recessed portion;

FIG. 7 is an enlarged side cross-sectional view of a relevant portion showing a state in which the elastic locking portion is inserted into the latching recessed portion and thus the elastic locking portion is elastically deformed; and

FIG. 8 is an enlarged side cross-sectional view of a relevant portion showing a state in which the elastic locking portion and the locking protrusion are locked to each other.

### DETAILED DESCRIPTION OF PREFERRED EMBODIMENTS

First, aspects of the present disclosure will be listed and described.

(1) An electrical junction box of the present disclosure includes:

a first case; and a second case, wherein the first case includes: a first body; an open surface that faces the first body and is open in a first direction; a side surface portion that faces in a lateral direction intersecting the first direction; and a locking protrusion that protrudes in the lateral direction from the side surface portion, the second case includes: a second body that closes the open surface; and an elastic locking portion, and the elastic locking portion includes: a base end portion that protrudes from the second body in the lateral direction; a locking body that is disposed away from the side surface portion in the lateral direction and is locked to the locking protrusion to keep the first case and the second case in a closed state; and a bent portion that connects the base end portion and the locking body.

With the aspect (1) above, even if the extending length of the locking body of the elastic locking portion is reduced, the base end portion compensates for the reduction in the length of the locking body, thus making it possible to ensure ease of elastic deformation of the elastic locking portion. In particular, the base end portion protrudes from the second body that closes the open surface of the first case, thus making it possible to prevent the second case from increasing in size in the first direction due to the presence of the elastic locking portion.

(2) In the electrical junction box according to the aspect (1) above, it is preferable that the bent portion is curved from the base end portion to the locking body.

With the aspect (2) above, it is possible to suppress concentration of stress in the bent portion when the elastic locking portion is elastically deformed.

(3) In the electrical junction box according to the aspect (1) or (2) above, the elastic locking portion may be provided with a locking hole to which the locking protrusion is fitted, and the locking hole may pass through an area that includes the base end portion and the locking body.

With the aspect (3) above, the elastic locking portion is easy to elastically deform.

(4) In the electrical junction box according to any one of the aspects (1) to (3) above, the second case may include: a cover portion that protrudes from the second body and covers the elastic locking portion from the lateral direction; and a bending allowance space that is located between the cover portion and the elastic locking portion and allows bending deformation of the elastic locking portion.

With the aspect (4) above, the cover portion can suppress entrance of foreign matter into the electrical junction box through the locking hole while allowing the elastic locking portion to be elastically deformed. In addition, it is possible to prevent the elastic locking portion from being excessively bent.

(5) In the electrical junction box according to the aspect (4) above, the second case may include a second side wall that intersects the second body and protrudes, and the cover portion may be a portion of the second side wall and be continuous and flush with a portion therearound in the second side wall.

With the aspect (5) above, it is possible to suppress formation of protrusions and recessed portions particularly on the side wall of the inner surface of the fixation-side portion of a die, thus making it possible to simplify the structure of the die.

(6) In the electrical junction box according to the aspect (4) above, the second body may be a blocking wall having a flat plate shape and be provided with a through hole that passes therethrough in the first direction corresponding to a thickness direction, and a root of the base end portion may be coupled to a surface inside the through hole.

With the aspect (6) above, it is possible to utilize the through hole to confirm whether or not the elastic locking portion and the locking protrusion are locked to each other.

(7) In the electrical junction box according to the aspect (6) above, the second body may include a peripheral wall portion that rims an opening on an outside in the first direction of the through hole.

With the aspect (7) above, when a liquid such as water attaches to the surface of the second body (closing wall), the peripheral wall portion can suppress entrance of the liquid through the through hole.

The following describes specific embodiments of an electrical junction box of the present disclosure with reference to the drawings. Note that the present disclosure is not limited to these embodiments and is defined by the scope of the appended claims, and all changes that fall within the same essential spirit as the scope of the claims are intended to be included therein.

### Embodiment 1

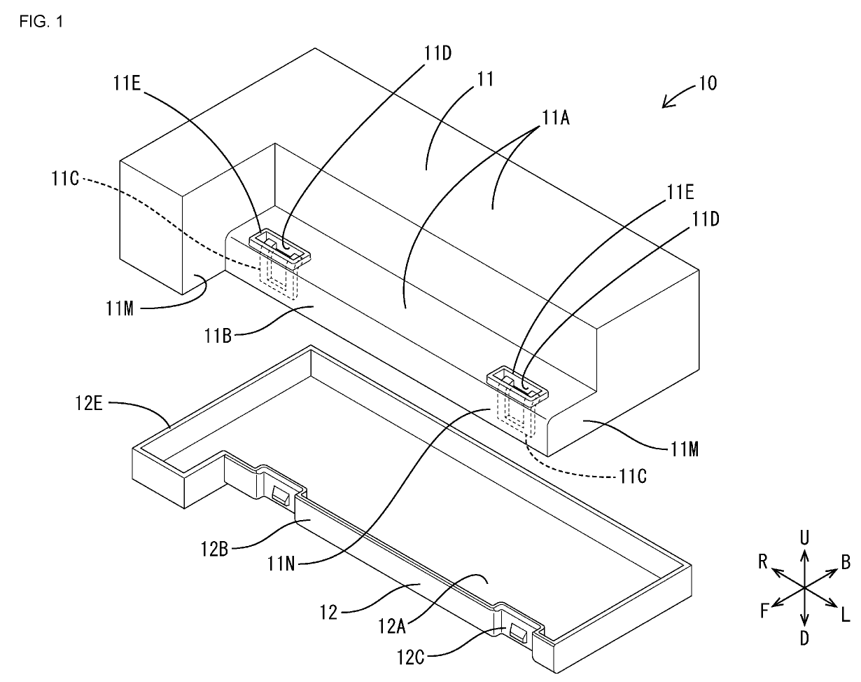

A specific example of Embodiment 1 will be described with reference to FIGS. 1-8. An electrical junction box 10 according to Embodiment 1 is to be mounted in, for example, a vehicle such as an electric vehicle. In the diagrams, the "front side", the "back side", the "upside", the "downside", the "right side", and the "left side" are represented by "F", "B", "U", "D", "R", and "L", respectively. Note that the reference directions are defined as a matter of convenience, and these directions do not necessarily coincide with the corresponding directions when the electrical junction box 10 is mounted in a vehicle or the like. For example, the up-down direction is not limited to the gravity direction.

The electrical junction box 10 contains, for example, electrical components such as a relay and a register, busbars, and the like (not illustrated). As shown in FIG. 1, the electrical junction box 10 includes a second case 11 serving as an upper case, and a first case 12 serving as a lower case. The second case 11 and the first case 12 are made of, for example, a synthetic resin.

### Configuration of First Case

The first case 12 has a box shape that is open upward. The first case 12 includes a first body 12A that spreads in a flat plate shape with the thickness direction extending in the vertical direction, and a side surface portion 12B that rises from the outer peripheral edge of the first body 12A. The side surface portion 12B has a flat plate shape with the thickness direction extending laterally, and faces in a lateral direction intersecting the vertical direction (first direction). The upper edge portion of the side surface portion 12B is a portion of an open surface 12E that faces the first body 12A and is open upward (in the first direction).

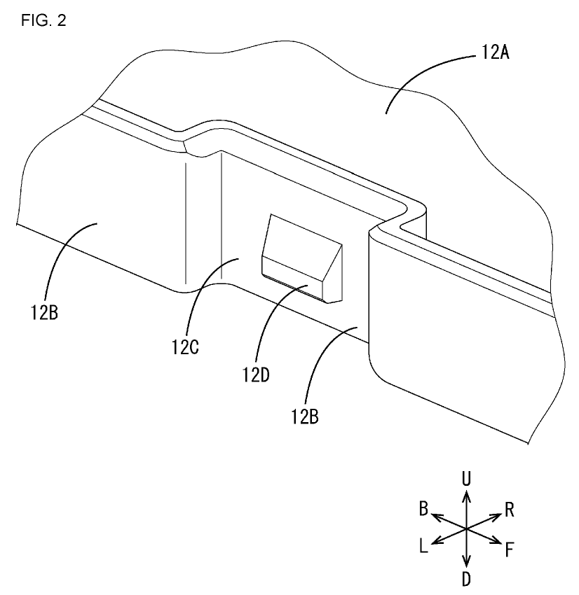

As shown in FIG. 2, the side surface portion 12B is provided with fitting recessed portions 12C and locking protrusions 12D. Each of the fitting recessed portions 12C is formed by recessing a portion of the side surface portion 12B toward the inside of the first case 12.

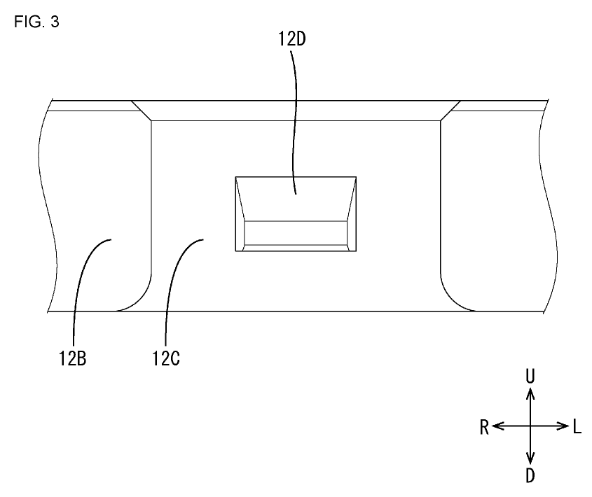

Each of the locking protrusions 12D protrudes forward (laterally) from the center in the vertical direction and the left-right direction of the front surface in the fitting recessed portion 12C. In other words, the locking protrusion 12D protrudes in the lateral direction from the side surface portion 12B. The upper side of the locking protrusion 12D is inclined such that the forward protruding length decreases toward the upper end. Both sides of the locking protrusion 12D in the left-right direction are inclined such that the forward protruding lengths decrease toward both ends in the left-right direction (see FIG. 3). The front edge at the lower end of the locking protrusion 12D is chamfered.

### Configuration of Second Case

As shown in FIG. 1, the second case 11 has a box shape that is open downward. The second case 11 includes a second body 11A, a second side wall 11B that intersects the second body 11A and protrudes, and elastic locking portions 11C. The second body 11A is a blocking wall that spreads in a flat plate shape with the thickness direction extending in the vertical direction. The second body 11A is provided with through holes 11D that pass therethrough in the vertical direction (first direction) corresponding to the thickness direction. Each of the through holes 11D has a rectangular shape elongate in the left-right direction along the front edge portion of the second body 11A. The second body 11A includes peripheral wall portions 11E that each rim the opening on the outside in the first direction of the through hole 11D. Each of the peripheral wall portions 11E has a polygonal tube shape and is in communication with the through hole 11D.

The second side wall 11B has a flat plate shape with the thickness direction extends laterally, and hangs from the second body 11A.

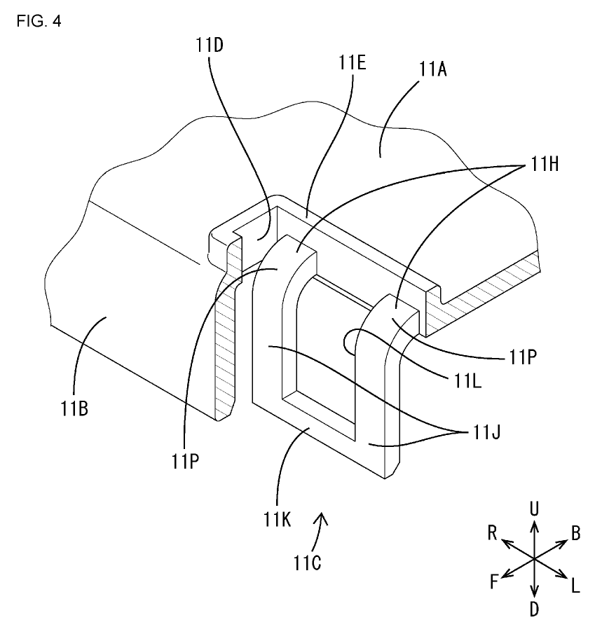

As shown in FIG. 4, each of the elastic locking portions 11C includes a pair of base end portions 11H, a pair of bent portions 11P, a pair of locking bodies 11J, and a locking hole 11L. The roots of the pair of base end portions 11H are coupled to the surface inside the through hole 11D. In other words, the base end portions 11H protrude forward (in the lateral direction) from the second body 11A. The pair of base end portions 11H are disposed away from each other in the left-right direction. The pair of bent portions 11P are continuous with the front end of the base end portions 11H, are curved downward, and extend. The pair of locking bodies 11J are continuous with the lower ends of the bent portions 11P and extend downward. Each of the bent portions 11P is curved from the base end portion 11H to the locking body 11J. The bent portion 11P connects the base end portion 11H and the locking body 11J. A locking piece 11K is provided at the lower end portions of the locking bodies 11J. The locking piece 11K extends in the left-right direction and connects the lower end portions of the locking bodies 11J.

The locking hole 11L is formed by being surrounded by the pair of base end portions 11H, the pair of bent portions 11P, the pair of locking bodies 11J, the locking piece 11K, and the surface inside the through hole 11D with which the pair of base end portions 11H are continuous. In other words, the locking hole 11L passes through an area between the roots of the base end portions 11H and the lower end portions (distal end portions) of the locking bodies 11J. The thus formed elastic locking portion 11C is elastically deformable in the front-rear direction using, as fulcra, the base end portions 11H that are continuous with the through hole 11D in the pair of base end portions 11H.

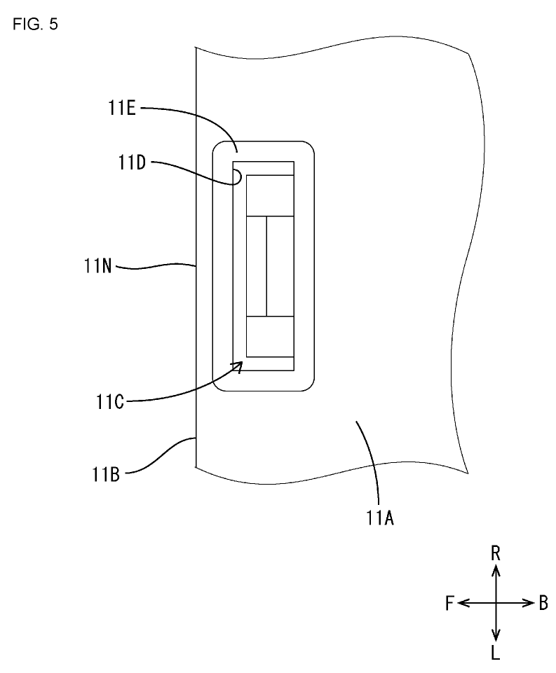

As viewed from above, the elastic locking portion 11C is disposed within a range in which the through hole 11D is formed (see FIG. 5). In other words, the through hole 11D is formed such that the elastic locking portion 11C is exposed upward.

A portion of the second side wall 11B serves as a cover portion 11N that covers the elastic locking portion 11C from the front side (lateral side) (see FIG. 5). In other words, the cover portion 11N protrudes from the second body 11A and covers the elastic locking portion 11C from the lateral side.

The cover portion 11N is continuous and flush with a portion 11M therearound in the second side wall 11B (see FIG. 1). The cover portion 11N is located on the front side relative to the elastic locking portion 11C (see FIG. 5). The cover portion 11N covers the locking hole 11L from the front side (lateral side) (see FIG. 5).

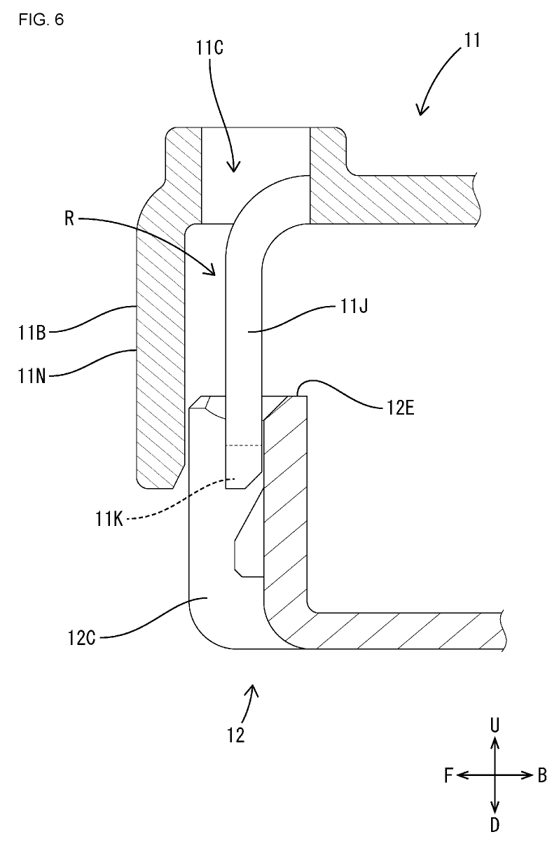

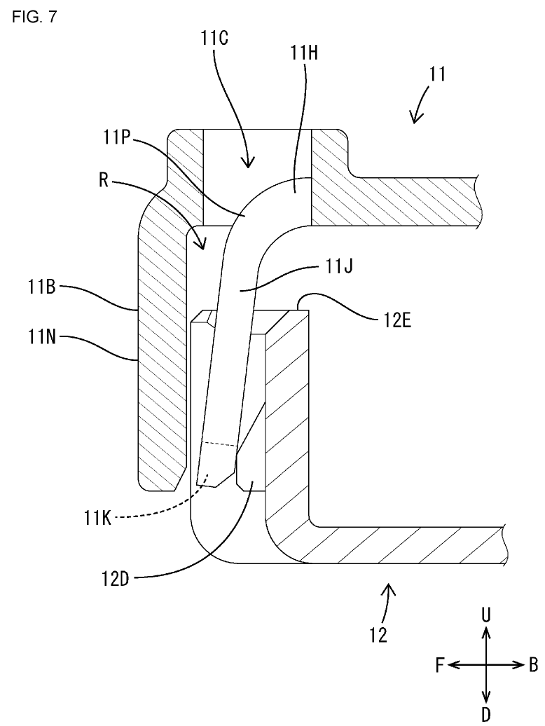

As shown in FIG. 6, a bending allowance space R is formed between the cover portion 11N and the elastic locking portion 11C. The bending allowance space R is disposed so as to be sandwiched between the cover portion 11N and the elastic locking portion 11C in the front-rear direction. The elastic locking portion 11C that has been elastically deformed forward enters the bending allowance space R (see FIG. 7). That is to say, the bending allowance space R is a space in which bending deformation of the elastic locking portion 11C is allowed.

### Example of Procedure for Coupling First Case and Second Case

First, as shown in FIG. 1, the open side of the second case 11 and the open surface 12E of the first case 12 are arranged so as to face each other. Subsequently, the second case 11 and the first case 12 are arranged to have the same orientation such that each of the elastic locking portions 11C is disposed above the fitting recessed portion 12C. Then, the second case 11 and the first case 12 are brought close to each other, and the first case 12 is inserted into the inside of the second side wall 11B. At this time, the locking bodies 11J of the elastic locking portion 11C extend toward the first case 12 (see FIG. 6).

At this time, as shown in FIG. 6, the locking piece 11K that connects the lower edge portions of the locking bodies 11J enters the fitting recessed portion 12C from above. When the first case 12 is further inserted into the inside of the second side wall 11B, the locking piece 11K comes into contact with the locking protrusion 12D and slides downward while being in contact with the front surface of the locking protrusion 12D, as shown in FIG. 7. Thus, the base end portions 11H, the bent portions 11P, and the locking bodies 11J of the elastic locking portion 11C are elastically deformed forward. At this time, the bent portions 11P and the locking bodies 11J enter the bending allowance space R.

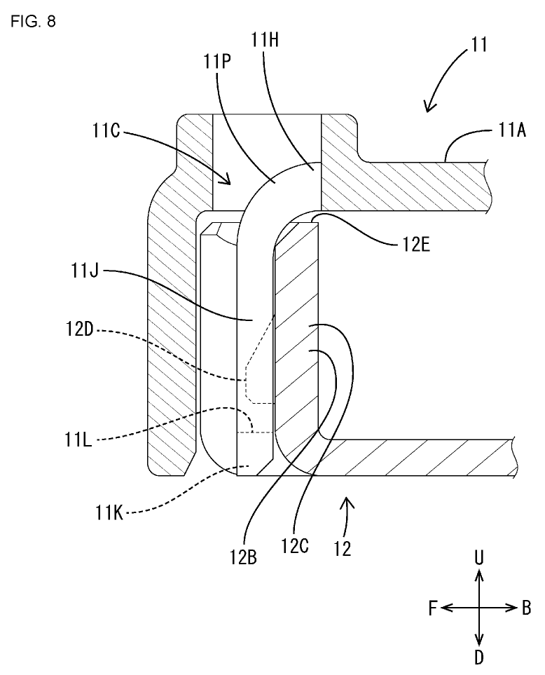

When the first case 12 is further inserted into the inside of the second side wall 11B, the locking piece 11K passes downward over the locking protrusion 12D as shown in FIG. 8. Thus, the base end portions 11H, the bent portions 11P, and the locking bodies 11J that were elastically deformed forward are elastically restored, and the locking piece 11K is disposed below the locking protrusion 12D. At this time, the locking protrusion 12D is fitted in the locking hole 11L. In this manner, the second case 11 and the first case 12 are kept in a closed state due to the elastic locking portion 11C being locked to the locking protrusion 12D. At this time, the second body 11A of the second case 11 closes the open surface 12E of the first case 12. At this time, the locking body 11J is disposed on the front side (lateral side) relative to the side surface portion 12B.

As described above, the electrical junction box 10 according to Embodiment 1 includes the first case 12 and the second case 11. The first case 12 includes the first body 12A, the open surface 12E that faces the first body 12A and is open upward (in the first direction), the side surface portion 12B that faces in a lateral direction intersecting the vertical direction (first direction), and the locking protrusions 12D that protrude in the lateral direction from the side surface portion 12B. The second case 11 includes the second body 11A that closes the open surface 12E, and the elastic locking portions 11C. Each of the elastic locking portions 11C includes the base end portions 11H that protrude in the lateral direction from the second body 11A, the locking bodies 11J that are disposed away from the side surface portion 12B in the lateral direction and are locked to the locking protrusion 12D to keep the first case 12 and the second case 11 in the closed state, and the bent portions 11P that connect the base end portions 11H and the locking bodies 11J.

With this configuration, even if the extending lengths of the locking bodies 11J of the elastic locking portion 11C are reduced, the base end portions 11H compensate for the reduction in the lengths of the locking bodies 11J, thus making it possible to ensure ease of elastic deformation of the elastic locking portion 11C. In particular, the base end portions 11H protrude from the second body 11A that closes the open surface 12E of the first case 12, thus making it possible to prevent the second case 11 from increasing in size in the vertical direction (first direction) due to the presence of the elastic locking portion 11C.

Each of the bent portions 11P is curved from the base end portion 11H to the locking body 11J. With this configuration, it is possible to suppress concentration of stress in the bent portion 11P when the elastic locking portion 11C is elastically deformed.

The elastic locking portion 11C is provided with the locking hole 11L to which the locking protrusion 12D is fitted. The locking hole 11L passes through an area that includes the base end portions 11H and the locking bodies 11J. With this configuration, the elastic locking portion 11C is easy to elastically deform.

The second case 11 includes the cover portions 11N that each protrude from the second body 11A and cover the elastic locking portion 11C from the lateral side, and the bending allowance spaces R that are each located between the cover portion 11N and the elastic locking portion 11C and allow the bending deformation of the elastic locking portion 11C. With this configuration, the cover portion 11N can suppress entrance of foreign matter into the electrical junction box 10 through the locking hole 11L while allowing the elastic locking portion 11C to be elastically deformed. In addition, it is possible to prevent the elastic locking portion 11C from being excessively bent.

The second case 11 includes the second side wall 11B that intersects the second body 11A and protrudes. The cover portion 11N is a portion of the second side wall 11B and is continuous and flush with a portion 11M therearound in the second side wall 11B. With this configuration, it is possible to suppress formation of protrusions and recessed portions particularly on the side wall of the inner surface of the fixation-side portion of a die, thus making it possible to simplify the structure of the die.

The second body 11A is a blocking wall having a flat plate shape and is provided with through holes 11D that pass therethrough in the vertical direction (first direction) corresponding to the thickness direction. The roots of the base end portions 11H are coupled to the surfaces inside the through holes 11D. With this configuration, it is possible to utilize the through holes 11D to confirm whether or not the elastic locking portion 11C and the locking protrusion 12D are locked to each other.

The second body 11A includes peripheral wall portions 11E that each rim the opening above (on the outside in the first direction) of the through hole 11D. With this configuration, when a liquid such as water attaches to the surface of the second body 11A, the peripheral wall portions 11E can suppress entrance of the liquid through the through holes 11D.

### Other Embodiments of the Present Disclosure

The embodiments disclosed herein are exemplary in all respects, and should be construed as being not limitative.

Unlike the embodiment above, a configuration may be employed in which the bent portions are not curved. For example, a configuration in which each of the bent portion extends so as to intersect the base end portion and the locking body at 45 degrees or a configuration in which each of the bent portions are bent at a right angle may be employed.

Unlike the embodiment above, the locking hole may be formed only at the distal end portions of the locking bodies.

Unlike the embodiment above, a configuration may be employed in which the cover portions are not provided, that is, the elastic locking portions are exposed to the lateral side.

Unlike the embodiment above, the base end portions of the elastic locking portion may protrude from the inner surface of the peripheral wall portion. In this case, it is possible to ensure the lengths of the bodies, and thus elastic deformation can be more easily caused.

Unlike the embodiment above, a configuration may be employed in which the peripheral wall portions are not provided.

What is claimed is:

1. An electrical junction box comprising:
a first case; and
a second case,
wherein the first case includes:
a first body;
an open surface that faces the first body and is open in a first direction;
a side surface portion that faces in a lateral direction intersecting the first direction; and
a locking protrusion that protrudes in the lateral direction from the side surface portion,
the second case includes:
a second body that closes the open surface; and
an elastic locking portion, and
the elastic locking portion includes:
a base end portion that protrudes from the second body in the lateral direction;
a locking body that is disposed away from the side surface portion in the lateral direction and is locked to the locking protrusion to keep the first case and the second case in a closed state; and
a bent portion that connects the base end portion and the locking body.

2. The electrical junction box according to claim 1, wherein the bent portion is curved from the base end portion to the locking body.

3. The electrical junction box according to claim 1,
wherein the elastic locking portion is provided with a locking hole to which the locking protrusion is fitted, and
the locking hole passes through an area that includes the base end portion and the locking body.

4. The electrical junction box according to claim 1,
wherein the second case includes:
a cover portion that protrudes from the second body and covers the elastic locking portion from the lateral direction; and
a bending allowance space that is located between the cover portion and the elastic locking portion and allows bending deformation of the elastic locking portion.

5. The electrical junction box according to claim 4,
wherein the second case includes a second side wall that intersects the second body and protrudes, and
the cover portion is a portion of the second side wall and is continuous and flush with a portion therearound in the second side wall.

6. The electrical junction box according to claim 1,
wherein the second body is a blocking wall having a flat plate shape and is provided with a through hole that passes therethrough in the first direction corresponding to a thickness direction, and
a root of the base end portion is coupled to a surface inside the through hole.

7. The electrical junction box according to claim 6, wherein the second body includes a peripheral wall portion that rims an opening on an outside in the first direction of the through hole.
